(19) United States
(12) Patent Application Publication
(10) Pub. No.: US 2022/0279859 A1
(43) Pub. Date: Sep. 8, 2022

(54) AEROSOL GENERATING DEVICE

(71) Applicant: KT&G CORPORATION, Daejeon (KR)

(72) Inventors: Byung Sung CHO, Gwangmyeong-si (KR); Min Kyu KIM, Seoul (KR); Won Kyeong LEE, Guri-si (KR); Jong Sub LEE, Seongnam-si (KR)

(73) Assignee: KT&G CORPORATION, Daejeon (KR)

(21) Appl. No.: 17/628,791

(22) PCT Filed: Apr. 13, 2021
(86) PCT No.: PCT/KR2021/004666

§ 371 Date: Jan. 20, 2022

(30) Foreign Application Priority Data
Apr. 14, 2020 (KR) 10-2020-0045241

(51) Int. Cl. A24F 40/60; A24F 40/57; A24F 40/40; H01M 50/247

(52) U.S. Cl. CPC A24F 40/60; A24F 40/57; A24F 40/40; H01M 50/247; H02J 7/0063

(57) ABSTRACT

An aerosol generating device includes a first electrode and a second electrode, which are arranged apart from each other on an outer surface of a main body, and supplies power to a controller only when the first electrode and the second electrode are in electrical contact with each other by user's manipulation, such that power consumption in a standby mode may be significantly reduced.

### TECHNICAL FIELD

One or more embodiments relate to an aerosol generating device, and more particularly, to an aerosol generating device in which standby power consumption may be reduced.

### BACKGROUND ART

Recently, the demand for alternative methods for overcoming the shortcomings of general cigarettes has increased. For example, there is growing demand for aerosol generating device that generates aerosols by heating an aerosol generating material in cigarettes or liquid storages rather than by combusting cigarettes.

### DISCLOSURE

### Technical Problem

Some aerosol generating devices include a sensor for detecting a cigarette. In this case, power is consumed even in the standby mode because power needs to be continuously supplied to a sensor.

The technical problems of the present disclosure are not limited to the above-described description, and other technical problems may be derived from the embodiments to be described hereinafter.

### Technical Solution

According to an aspect of the present disclosure, an aerosol generating device includes a main body, a heater accommodated in the main body and configured to heat an aerosol generating material, a controller accommodated in the main body and configured to heat the heater, and a power supply unit comprising a first electrode and a second electrode arranged apart from each other on an outer surface of the main body, and configured to supply power to the controller when the first electrode and the second electrode are connected to each other.

### Advantageous Effects

In an aerosol generating device according to one or more embodiments, a first electrode and a second electrode may be apart from each other and power is supplied only when the first and second electrodes are connected, such that power consumption in a standby mode may be significantly reduced.

In addition, because, in the aerosol generating device according to one or more embodiments, power is automatically supplied to a controller in response to the movement of a slider so that user convenience may be improved.

In addition, because, in the aerosol generating device according to one or more embodiments, power is supplied to the controller in response to a user's touch input so that accidental operation of the device against the user's intention may be prevented.

The effects of the present disclosure are not limited to the above-described effects, and effects that are not mentioned will be clearly understood by those of ordinary skill in the art from the present specification and the accompanying drawings.

### DESCRIPTION OF DRAWINGS

FIG. 1 is an exploded perspective view schematically illustrating a coupling relationship between a replaceable cartridge containing an aerosol generating material and an aerosol generating device including the same, according to an embodiment.

FIG. 2 is a perspective view of an exemplary operating state of the aerosol generating device according to the embodiment illustrated in FIG. 1.

FIG. 3 is a perspective view of another exemplary operating state of the aerosol generating device according to the embodiment illustrated in FIG. 1.

FIG. 4 is a part of a side view of the aerosol generating device of FIG. 1 according to a viewing direction A1.

FIG. 5 is a block diagram illustrating the configuration of hardware of an aerosol generating device according to an embodiment.

FIG. 6 is a circuit diagram of a power supply unit of FIG. 6.

FIGS. 7 through 9 illustrate examples of a power supply method according to a first embodiment.

FIGS. 10 through 12 illustrate examples of a power supply method according to a second embodiment.

FIGS. 13 through 15 illustrate examples of a power supply method according to a third embodiment.

### BEST MODE

An aerosol generating device according to an embodiment may include a main body, a heater accommodated in the main body and configured to heat an aerosol generating material, a controller accommodated in the main body and configured to heat the heater, and a power supply unit comprising a first electrode and a second electrode arranged apart from each other on an outer surface of the main body, and configured to supply power to the controller when the first electrode and the second electrode are connected to each other.

The aerosol generating device may further include a slider comprising at least one conductive member arranged on an inner surface of the slider and coupled to the main body to be movable between a first position and a second position, and the conductive member may connect the first electrode and the second electrode to each other when the slider is at the second position.

The first electrode may include a first protrusion, and the second electrode may include a second protrusion, the conductive member may include coupling grooves which are coupled to the first protrusion and the second protrusion when the slider is at the second position.

The first electrode and the second electrode may be connected to each other by a user's touch input.

The aerosol generating device may further include a slider including a first conductive member and a second conductive member arranged on an inner surface of the slider, and coupled to the main body to be movable between the first position and the second position, wherein, when the slider is at the second position, the first conductive member may be in contact with the first electrode, and the second conductive member may be in contact with the second electrode.

The first electrode and the second electrode may be connected to each other by the user's touch input that connects the first conductive member and the second conductive member to each other.

The first electrode and the second electrode may be arranged on one side surface of the main body.

The first electrode and the second electrode may be arranged symmetrically with respect to a central longitudinal line of the main body.

The first electrode and the second electrode may be arranged apart from each other along a central longitudinal line of the main body.

The first electrode is arranged on one side surface of the main body, and the second electrode may be arranged on the other side surface of the main body.

The aerosol generating device may further include a battery configured to supply power to the controller.

The power supply unit may further include a switching element configured to connect the battery and the controller when the first electrode and the second electrode are connected to each other, and a resistive element configured to cut off an overvoltage of the battery.

The switching element may include an NPN transistor.

The first electrode may be connected to a positive terminal of the battery, and the second electrode may be connected to a base terminal of the NPN transistor, and an emitter terminal of the NPN transistor may be connected to the controller, and a collector terminal of the NPN transistor may be connected to the resistive element, and the resistive element may be connected to a negative terminal of the battery.

### MODE FOR INVENTION

With respect to the terms used to describe the various embodiments, general terms which are currently and widely used are selected in consideration of functions of structural elements in the various embodiments of the present disclosure. However, meanings of the terms can be changed according to intention, a judicial precedence, the appearance of new technology, and the like. In addition, in certain cases, a term which is not commonly used can be selected.

In such a case, the meaning of the term will be described in detail at the corresponding portion in the description of the present disclosure. Therefore, the terms used in the various embodiments of the present disclosure should be defined based on the meanings of the terms and the descriptions provided herein.

In addition, unless explicitly described to the contrary, the word “comprise” and variations such as “comprises” or “comprising” will be understood to imply the inclusion of stated elements but not the exclusion of any other elements. In addition, the terms “-er”, “-or”, and “module” described in the specification mean units for processing at least one function and/or operation and can be implemented by hardware components or software components and combinations thereof.

Hereinafter, the present disclosure will now be described more fully with reference to the accompanying drawings, in which exemplary embodiments of the present disclosure are shown such that one of ordinary skill in the art may easily work the present disclosure. The disclosure may, however, be embodied in many different forms and should not be construed as being limited to the embodiments set forth herein.

Hereinafter, embodiments of the present disclosure will be described in detail with reference to the drawings.

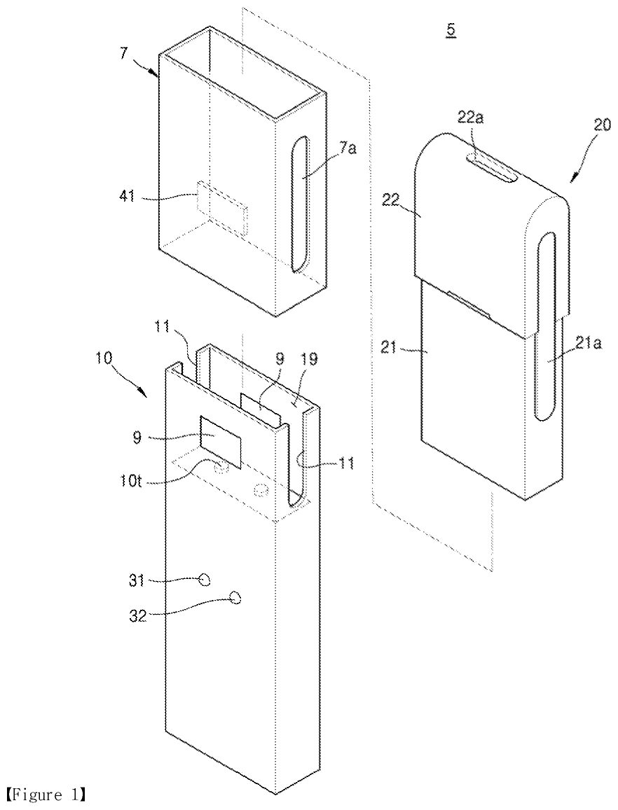

FIG. 1 is an exploded perspective view schematically illustrating a coupling relationship between a replaceable cartridge containing an aerosol generating material and an aerosol generating device including the same, according to an embodiment.

An aerosol generating device 5 according to the embodiment illustrated in FIG. 1 includes the cartridge 20 containing the aerosol generating material and a main body 10 supporting the cartridge 20.

The cartridge 20 may be coupled to the main body 10 in a state in which the aerosol generating material is accommodated therein. A portion of the cartridge 20 is inserted into an accommodation space 19 of the main body 10 so that the cartridge 20 may be mounted on the main body 10.

The cartridge 20 may contain an aerosol generating material in any one of, for example, a liquid state, a solid state, a gaseous state, or a gel state. The aerosol generating material may include a liquid composition. For example, the liquid composition may be a liquid including a tobacco-containing material having a volatile tobacco flavor component, or a liquid including a non-tobacco material.

For example, the liquid composition may include one component of water, solvents, ethanol, plant extracts, spices, flavorings, and vitamin mixtures, or a mixture of these components. The spices may include menthol, peppermint, spearmint oil, and various fruit-flavored ingredients, but are not limited thereto. The flavorings may include ingredients capable of providing various flavors or tastes to a user. Vitamin mixtures may be a mixture of at least one of vitamin A, vitamin B, vitamin C, and vitamin E, but are not limited thereto. In addition, the liquid composition may include an aerosol forming agent such as glycerin and propylene glycol.

For example, the liquid composition may include any weight ratio of glycerin and propylene glycol solution to which nicotine salts are added. The liquid composition may include two or more types of nicotine salts. Nicotine salts may be formed by adding suitable acids, including organic or inorganic acids, to nicotine. Nicotine may be a naturally generated nicotine or synthetic nicotine and may have any suitable weight concentration relative to the total solution weight of the liquid composition.

Acid for the formation of the nicotine salts may be appropriately selected in consideration of the rate of nicotine absorption in the blood, the operating temperature of the aerosol generating device 5, the flavor or savor, the solubility, or the like. For example, the acid for the formation of nicotine salts may be a single acid selected from the group consisting of benzoic acid, lactic acid, salicylic acid, lauric acid, sorbic acid, levulinic acid, pyruvic acid, formic acid, acetic acid, propionic acid, butyric acid, valeric acid, caproic acid, caprylic acid, capric acid, citric acid, myristic acid, palmitic acid, stearic acid, oleic acid, linoleic acid, linolenic acid, phenylacetic acid, tartaric acid, succinic acid, fumaric acid, gluconic acid, saccharic acid, malonic acid or malic acid, or a mixture of two or more acids selected from the group, but is not limited thereto.

The cartridge 20 is operated by an electrical signal or a wireless signal transmitted from the main body 10 to perform a function of generating aerosol by converting the phase of the aerosol generating material inside the cartridge 20 to a gaseous phase. The aerosol may refer to a gas in which vaporized particles generated from an aerosol generating material are mixed with air.

For example, the cartridge 20 may convert the phase of the aerosol generating material by receiving the electrical signal from the main body 10 and heating the aerosol generating material, or by using an ultrasonic vibration method, or by using an induction heating method. As another example, when the cartridge 20 includes its own power source, the cartridge 20 may generate aerosol by being operated by an electric control signal or a wireless signal transmitted from the main body 10 to the cartridge 20.

The cartridge 20 may include a liquid storage 21 accommodating the aerosol generating material therein, and an atomizer performing a function of converting the aerosol generating material of the liquid storage 21 to aerosol.

When the liquid storage 21 “accommodates the aerosol generating material” therein, it means that the liquid storage 21 functions as a container simply holding an aerosol generating material and that the liquid storage 21 includes therein an element impregnated with (containing) an aerosol generating material, such as a sponge, cotton, fabric, or porous ceramic structure.

The atomizer may include, for example, a liquid delivery element (wick) for absorbing the aerosol generating material and maintaining the same in an optimal state for conversion to aerosol, and a heater heating the liquid delivery element to generate aerosol.

The liquid delivery element may include at least one of, for example, a cotton fiber, a ceramic fiber, a glass fiber, and porous ceramic.

The heater may include a metallic material such as copper, nickel, tungsten, or the like to heat the aerosol generating material delivered to the liquid delivery element by generating heat using electrical resistance. The heater may be implemented by, for example, a metal wire, a metal plate, a ceramic heating element, or the like, and may be implemented by a conductive filament, wound on the liquid delivery element, or arranged adjacent to the liquid delivery element, by using a material such as a nichrome wire.

In addition, the atomizer may be implemented by a heating element in the form of a mesh or plate, which performs both the functions of absorbing the aerosol generating material and maintaining the same in an optimal state for conversion to aerosol without using a separate liquid delivery element and the function of generating aerosol by heating the aerosol generating material.

At least a portion of the liquid storage 21 of the cartridge 20 may include a transparent material so that the aerosol generating material accommodated in the cartridge 20 may be visually identified from the outside. The liquid storage 21 includes a protruding window 21a protruding from the liquid storage 21, so that the liquid storage 21 may be inserted into a groove 11 of the main body 10 when coupled to the main body 10. A mouthpiece 22 and the liquid storage 21 may be entirely formed of transparent plastic or glass, or only the protruding window 21a corresponding to a portion of the liquid storage 21 may be formed of a transparent material.

The main body 10 includes a connection terminal 10t arranged inside the accommodation space 19. When the liquid storage 21 of the cartridge 20 is inserted into the accommodation space 19 of the main body 10, the main body 10 may provide power to the cartridge 20 through the connection terminal 10t or supply a signal related to an operation of the cartridge 20 to the cartridge 20 through the connection terminal 10t.

The mouthpiece 22 is coupled to one end of the liquid storage 21 of the cartridge 20. The mouthpiece 22 is a portion of the aerosol generating device 5, which is to be inserted into a user's mouth. The mouthpiece 22 includes a discharge hole 22a for discharging aerosol generated from the aerosol generating material inside the liquid storage 21 to the outside.

The slider 7 is coupled to the main body 10 to move with respect to the main body 10. The slider 7 covers at least a portion of the mouthpiece 22 of the cartridge 20 coupled to the main body 10 or exposes at least a portion of the mouthpiece 22 to the outside by moving with respect to the main body 10. The slider 7 includes an elongated hole 7a exposing at least a portion of the protruding window 21a of the cartridge 20 to the outside.

The slider 7 has a container shape with a hollow space therein and both ends opened. The structure of the slider 7 is not limited to the container shape as shown in the drawing, and the slider 7 may have a bent plate structure having a clip-shaped cross-section, which is movable with respect to the main body 10 while being coupled to an edge of the main body 10, or a structure having a curved semi-cylindrical shape and a curved arc-shaped cross section.

The slider 7 includes at least one fixing magnetic body 9 for maintaining the position of the slider 7 with respect to the main body 10 and the cartridge 20. The magnetic body may include a permanent magnet or a material such as iron, nickel, cobalt, or an alloy thereof.

The fixing magnetic body 9 may be arranged on a movement path of the slider 7 that is moved with respect to the main body 10. Two fixing magnetic bodies 9 may be installed to face each other with the accommodation space 19 between them.

By using magnetism of the fixing magnetic body 9, the slider 7 may be stably maintained at the positions where the end of the mouthpiece 22 is covered or exposed.

The first electrode 31 and the second electrode 32 may be arranged to be apart from each other on an outer surface of the main body 10, and when the first electrode 31 and the second electrode 32 are connected to each other by the movement of the slider 7 or a user's touch input, power of a battery may be supplied to a controller.

In detail, the first electrode 31 and the second electrode 32 may be arranged to be apart from each other on the outer surface of the main body 10. FIG. 1 shows that the first electrode 31 and the second electrode 32 are arranged on the same side surface of the main body 10. However, according to an embodiment, the first electrode 31 may be arranged on one side surface of the outer surface of the main body 10, and the second electrode 32 may be arranged on the other side surface of the outer surface of the main body 10.

When the first electrode 31 and the second electrode 32 are arranged on the same side surface of the main body 10, the first electrode 31 and the second electrode 32 may be arranged symmetrically with respect to a central longitudinal line of the main body 10. Alternatively, when the first electrode 31 and the second electrode 32 are arranged on the same side surface of the main body 10, the first electrode 31 and the second electrode 32 may be arranged to be apart from each other along the central longitudinal line of the main body 10.

In other words, when the first electrode 31 and the second electrode 32 are arranged on the same side surface of the main body 10, the first electrode 31 and the second electrode 32 may be arranged in a direction perpendicular to the longitudinal direction of the main body 10 or may be arranged in the longitudinal direction of the main body 10. FIG. 1 illustrates that the first electrode 31 and the second electrode 32 are arranged in the direction perpendicular to the longitudinal direction of the main body 10, but embodiments are not limited thereto.

At least a portion of the first electrode 31 and the second electrode 32 may be exposed and thus may be in contact with a conductive member 41 included in the slider 7 or the user's finger. In FIG. 1, the exposed cross-section of the first electrode 31 and the second electrode 32 is illustrated in a shape having a circular cross-section, but is not limited thereto. For example, the exposed cross-section of the first electrode 31 and the second electrode 32 may be formed in a shape such as a rectangular shape, an elliptical shape, or a polygonal shape.

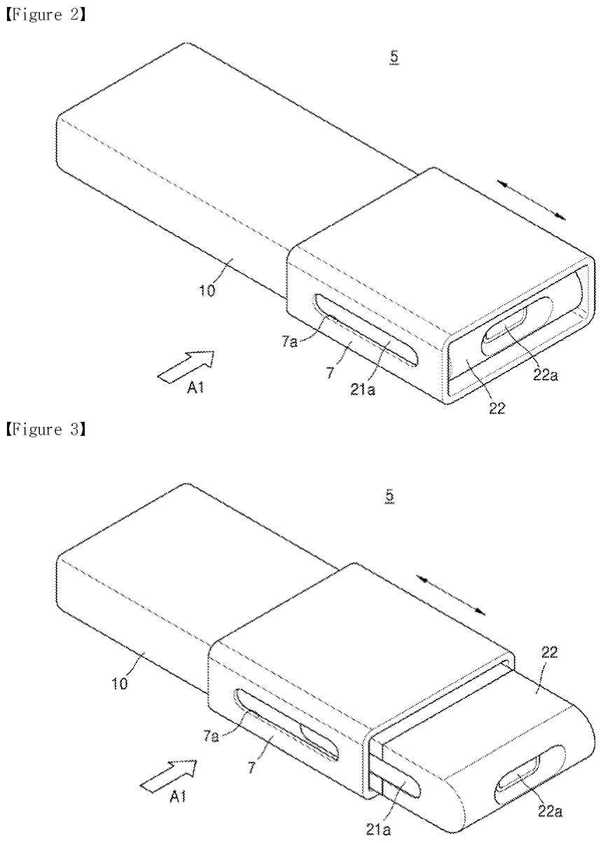

The conductive member 41 may be arranged on an inner surface of the slider 7. When the slider 7 is coupled to the main body 10 to be movable between the first position and the second position, the conductive member 41 may be in electrical contact with the first electrode 31 and the second electrode 32 at the second position of the slider 7. The first position refer to a position close to the mouthpiece 22 (see FIG. 2), and the second position refer to a position close to the center of the main body 10 (see FIG. 3).

Although one conductive member 41 is shown in FIG. 1, according to an embodiment, a plurality of conductive members 41 may be provided. In an embodiment, when the first electrode 31 and the second electrode 32 are arranged on different side surfaces of the main body 10, a first conductive member for contacting the first electrode 31 and a second conductive member for contacting the second electrode 32 may be arranged on the inner surface of the slider 7.

When the first electrode 31 and the second electrode 32 are in contact with each other by the conductive member 41 or the user's touch input, power of the battery may be transmitted to internal components.

In the aerosol generating device 5 according to the above-described embodiments, the main body 10, the cartridge 20, and the slider 7 have approximately rectangular cross-sectional shapes in a direction transverse to the longitudinal direction, but in the embodiments, the shape of the aerosol generating device 5 is not limited. The aerosol generating device 5 may have, for example, a cross-sectional shape of a circle, an ellipse, a square, or various polygonal shapes. In addition, the aerosol generating device 5 is not necessarily limited to a structure that extends linearly when extending in the longitudinal direction, and may extend a long way while being curved in a streamlined shape or bent at a preset angle in a specific area to be easily held by the user.

FIG. 2 is a perspective view of an exemplary operating state of the aerosol generating device according to the embodiment illustrated in FIG. 1.

In FIG. 2, the operating state is shown in which the slider 7 is moved to a position where the end of the mouthpiece 22 of the cartridge coupled to the main body 10 is covered. In a state where the slider 7 is moved to the position where the end of the mouthpiece 22 is covered, the mouthpiece 22 may be safely protected from external impurities and kept clean.

The user may check the remaining amount of aerosol generating material contained in the cartridge by visually checking the protruding window 21a of the cartridge through the elongated hole 7a of the slider 7. The user may move the slider 7 in the longitudinal direction of the main body 10 to use the aerosol generating device 5.

FIG. 3 is a perspective view of another exemplary operating state of the aerosol generating device according to the embodiment illustrated in FIG. 1.

In FIG. 3, the operating state is shown in which the slider 7 is moved to a position where the end of the mouthpiece 22 of the cartridge coupled to the main body 10 is exposed to the outside. In a state where the slider 7 is moved to the position where the end of the mouthpiece 22 is exposed to the outside, the user may insert the mouthpiece 22 into his or her mouth and absorb aerosol discharged through the discharge hole 22a of the mouthpiece 22.

Even when the slider 7 is moved to the position where the end of the mouthpiece 22 is exposed to the outside, the protruding window 21a of the cartridge is exposed to the outside through the elongated hole 7a of the slider 7, and thus, the user may visually check the remaining amount of aerosol generating material contained in the cartridge.

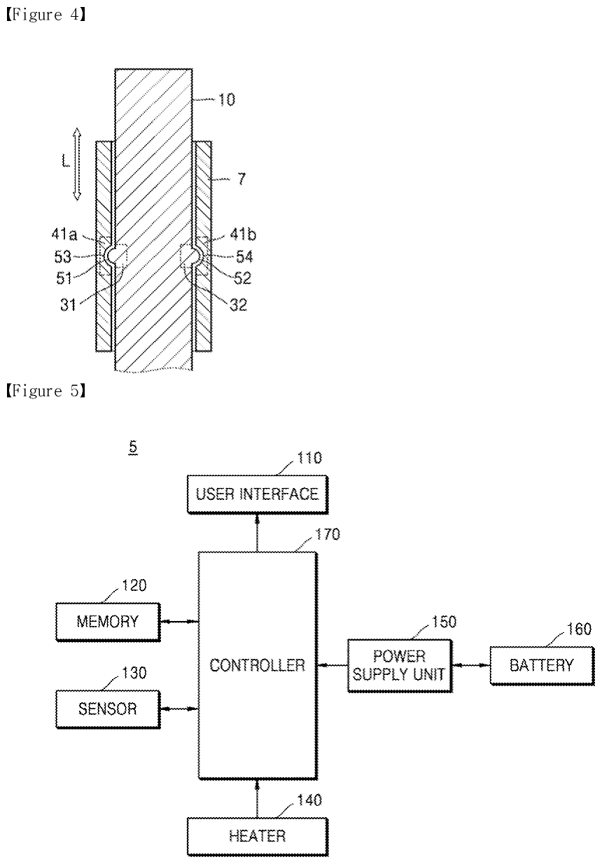

FIG. 4 is a part of a side view of the aerosol generating device of FIG. 1 according to a viewing direction A1.

Referring to FIG. 4, the slider 7 may be moved between a first position and a second position along the longitudinal direction L of the main body 10. The first position may mean a position close to an end of the main body where the mouthpiece 22 is located (see FIG. 2). The second position may mean a position close to the center of the main body 10 (see FIG. 3).

The slider 7 may be moved from the first position to the second position and from the second position to the first position along the main body 10.

The first electrode 31 and the second electrode 32 may be arranged to be apart from each other on the outer surface of the main body 10. For convenience of description, FIG. 4 shows that the first electrode 31 and the second electrode 32 are arranged on different side surfaces of the main body 10. However, depending on the embodiment, the first electrode 31 and the second electrode 32 may be arranged on the same side surface of the main body 10.

At least a portion of the first electrode 31 and the second electrode 32 may be exposed to the outside. The first electrode 31 may include a first protrusion 51, and the second electrode 32 may include a second protrusion 52.

The slider 7 may include at least one conductive member 41 (e.g., the first conductive member 41a and the second conductive member 41b in FIG. 4). For convenience of description, although FIG. 4 shows that the slider 7 includes the first conductive member 41a and the second conductive member 41b, according to an embodiment, the slider 7 may include one conductive member 41 that may be simultaneously in contact with the first electrode 31 and the second electrode 32.

The first conductive member 41a may include a first coupling groove 53, and the second conductive member 41b may include a second coupling groove 54.

When the slider 7 is at the second position, the first coupling groove 53 may be coupled to the first protrusion 51, and the second coupling groove 54 may be coupled to the second protrusion 52. As a result, the first electrode 31, the second electrode 32, and the conductive member 41 may be in electrical contact with each other.

As the conductive member 41 includes the first and second coupling grooves 53 and 54 and the first electrode 31 and the second electrode 32 include the first and second protrusions 52 and 53, the aerosol generating device 5 may stably fix the slider 7 at the second position, and the reliability of contact between the first electrode 31, the second electrode 32 and the conductive member 41 may be guaranteed. In addition, because the first and second coupling grooves 53 and 54 and the first and second protrusions 52 and 53 are coupled to one another only when a certain force is applied to the slider 7 along the longitudinal direction L of the main body 10, the malfunction of the device may be prevented.

FIG. 5 is a block diagram illustrating the configuration of an aerosol generating device according to an embodiment.

Referring to the drawing, the aerosol generating device 5 may include a user interface 110, a memory 120, a sensor 130, a heater 140, a power supply unit 150, a battery 160, and a controller 170. However, the internal structure of the aerosol generating device 5 is not limited to that shown in FIG. 5. Depending on the design of the aerosol generating device 5, it may be understood by those of ordinary skill in the art related to the present embodiment that some of the hardware configurations shown in FIG. 5 may be omitted or a new configuration may be added.

In an embodiment, the aerosol generating device 5 may include only the main body 10. In this case, the hardware configurations included in the aerosol generating device 5 may be located in the main body 10. In another embodiment, the aerosol generating device 5 may be arranged in the main body 10 and the cartridge 20 in a distributed manner. Certain components may be located in each of the main body 10 and the cartridge 20.

Hereinafter, a space in which each component included in the aerosol generating device 5 is located is not limited, and an operation of each component will be described.

The user interface 110 may provide information on the state of the aerosol generating device 5 to the user. The user interface 110 may include a display or lamp that outputs visual information, a motor that outputs haptic information, a speaker that outputs sound information, input/output (I/O) interfacing units (e.g., buttons or touch screens) that receive information input from a user or output information to the user, or terminals for data communication or receiving charging power, and various interfacing units such as a communication interfacing module for performing wireless communication (e.g., WI-FI, WI-FI Direct, Bluetooth, near-field communication (NFC), etc.) with external devices.

However, in the aerosol generating device 5, only some of the user interfaces 110 illustrated above may be selected and implemented.

The memory 120 that is hardware for storing various data to be processed in the aerosol generating device 5 may store data processed by the controller 170 and data to be processed. The memory 120 may be implemented in a variety of types such as random access memory (RAM) such as dynamic random access memory (DRAM), static random access memory (SRAM), read-only memory (ROM), and electrically erasable programmable read-only memory (EEPROM).

The aerosol generating device 5 may include at least one sensor 130. The result of sensing by at least one sensor 130 may be transmitted to the controller 170, and depending on the sensing result, the controller 170 may control the aerosol generating device 5 to perform various functions such as controlling the operation of the heater, limiting smoking, determining whether or not to insert a cigarette (or cartridge), and displaying a notification.

For example, at least one sensor 130 may include a puff detecting sensor. The puff detecting sensor may detect a user's puff based on any one of a temperature change, a flow change, a voltage change, and a pressure change.

Also, at least one sensor 130 may include a temperature detecting sensor. The temperature detecting sensor may detect temperature at which the heater 140 (or an aerosol generating material) is heated. The aerosol generating device 5 may include a separate temperature detecting sensor that detects the temperature of the heater 140, or instead of including a separate temperature detecting sensor, the heater 140 itself may serve as a temperature detecting sensor. Alternatively, the heater 140 may serve as a temperature detecting sensor and simultaneously, the aerosol generating device 5 may further include a separate temperature detecting sensor.

The heater 140 may receive power from the battery 160 according to the control of the controller 170. The heater 140 may heat the cigarette inserted into the aerosol generating device 5 by power supplied from the battery 160 or may heat the cartridge 20 mounted on the aerosol generating device 5.

The heater 140 may be located in the main body 10 of the aerosol generating device 5. Alternatively, when the aerosol generating device 5 includes the main body 10 and the cartridge 20, the heater 140 may be located in the cartridge 20. When the heater 140 is located in the cartridge 20, the heater 140 may receive power from the battery 160 located in least one of the main body 10 and the cartridge 20.

The heater 140 may be formed of any suitable electrically resistive material. For example, the suitable electrically resistive material may be a metal or a metal alloy including titanium, zirconium, tantalum, platinum, nickel, cobalt, chromium, hafnium, niobium, molybdenum, tungsten, tin, gallium, manganese, iron, copper, stainless steel, or nichrome, but is not limited thereto. Also, the heater 140 may be implemented as a metal heating wire, a metal hot plate on which an electrically conductive track is arranged, a ceramic heating body, or the like, but is not limited thereto.

In an embodiment, the heater 140 may be included in the cartridge 20. The cartridge 20 may include the heater 140, a liquid delivery element, and a liquid storage. The aerosol generating material accommodated in the liquid storage may be moved to the liquid delivery element, and the heater 140 may heat the aerosol generating material absorbed into the liquid delivery element to generate an aerosol. For example, the heater 140 may include a material such as nickel chromium and may be wound around the liquid delivery element or arranged adjacent to the liquid delivery element.

In another example, the heater 140 may heat the cigarette inserted into the accommodation space of the aerosol generating device 5. As the cigarette is accommodated in the accommodation space of the aerosol generating device 5, the heater 140 may be located inside and/or outside the cigarette. Thus, the heater 140 may heat the aerosol generating material inside the cigarette to generate an aerosol.

The heater 140 may be an induction heater. The heater 140 may include an electrically conductive coil for heating the cigarette or cartridge 20 by using an induction heating method, and a susceptor that may be heated by the induction heater may be included in the cigarette or cartridge 20.

The battery 160 may supply power so that the heater 140 may be heated. Also, the battery 160 may supply power required for the operations of other hardware configurations, i.e., the sensor 130, the user interface 110, the memory 120, and the controller 170, which are included in the aerosol generating device 5. The battery 160 may be a rechargeable battery or a disposable battery. For example, the battery 160 may be a lithium polymer (LiPoly) battery, but is not limited thereto.

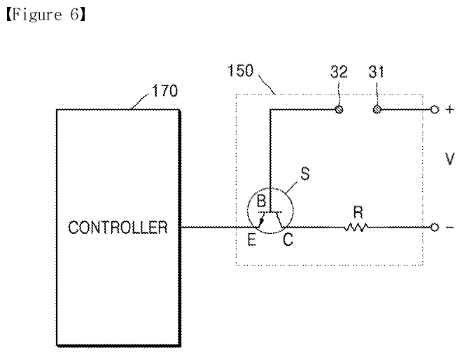

The power supply unit 150 may transfer power from the battery 160 to the controller 170 based on operating modes of the aerosol generating device 5. To this end, the power supply unit 150 may include a first electrode (see 31 of FIG. 6) and a second electrode (see 32 of FIG. 6).

In detail, the power supply unit 150 may cut off power supplied to the controller 170 in a standby mode in which the first electrode 31 and the second electrode 32 are not connected to each other.

The standby mode refers to an operating mode in which power required for operations of internal components of the device is cut off, and may be referred to as different names such as a power saving mode, a sleep mode, or the like.

In a smoking mode in which the first electrode 31 and the second electrode 32 are connected to each other, the power supply unit 150 may supply power to the controller 170, and the controller 170 may control the heater 140 to heat an aerosol generating material.

The first electrode 31 and the second electrode 32 may be connected to each other by the movement of the slider 7 or the user's touch input.

The controller 170 may be hardware that controls the overall operation of the aerosol generating device 5. The controller 170 may include at least one processor. A processor can be implemented as an array of a plurality of logic gates or can be implemented as a combination of a general-purpose microprocessor and a memory in which a program executable in the microprocessor is stored. Also, it may be understood by those skilled in the art to which the present embodiment belongs, that the processor may be implemented with other types of hardware.

The controller 170 may analyze the result sensed by at least one sensor 130 and may control subsequent processes to be performed subsequently.

The controller 170 may control power supplied to the heater 140 so that the operation of the heater 140 starts or is terminated, based on the result of sensing by at least one sensor 130. In addition, the controller 170 may control the amount of power supplied to the heater 140 and time when power is supplied, so that the heater 140 may be heated up to a certain temperature or maintained at an appropriate temperature, based on the result of sensing by at least one sensor 130.

Although not shown in FIG. 5, the aerosol generating device 5 may constitute an aerosol generating system together with a separate cradle. For example, the cradle may be used to charge the battery 160 of the aerosol generating device 5. For example, while being accommodated in an accommodation space of the cradle, the aerosol generating device 5 may receive power from a battery of the cradle to charge the battery 160 of the aerosol generating device 5.

FIG. 6 is a circuit diagram of the power supply unit of FIG. 5.

Referring to FIG. 6, the power supply unit 150 may include a first electrode 31, a second electrode 32, a switching element S, and a resistive element R. According to an embodiment, the power supply unit 150 may be a component including the battery 160 of FIG. 5.

The switching element S may be a bipolar junction transistor (BJT) or a field effect transistor (FET). Hereinafter, it is assumed that an NPN transistor is used, but embodiment are not limited thereto.

The first electrode 31 may be connected to a positive terminal of the battery 160, and the second electrode 32 may be connected to a base terminal B of the NPN transistor. Also, an emitter terminal E of the NPN transistor may be connected to the controller 170, and a collector terminal C of the NPN transistor may be connected to the resistive element R.

The resistive element R may serve to cut off an overvoltage of the battery 160, and it may be connected in series between the collector terminal C of the NPN transistor and a negative terminal of the battery 160.

The first electrode 31 and the second electrode 32 may be connected to each other by the conductive member 41 included in the slider 7 or by the user's touch input. In other words, an electrical contact may be made between the first electrode 31 and the second electrode 32.

When the first electrode 31 and the second electrode 32 are in electrical contact with each other, a closed loop may be formed along the battery 16, the first electrode 31, the second electrode 32, the switching element S, and the resistive element R. Thus, an amplified current in a forward direction may flow between the collector terminal C and the emitter terminal E. In other words, the current of the battery 160 may be supplied to the controller 170.

Alternatively, the first electrode 31 and the second electrode 32 may be connected to each other by the user's touch input.

In detail, when the user connects the first electrode 31 and the second electrode 32 to each other by using his/her own finger, a forward voltage may be applied between the base terminal B and the emitter terminal E of the switching element S. Because the forward voltage may be set to a relatively low voltage such as 0.6 V, even with the user's touch input, a sufficient voltage greater than or equal to the forward voltage may be applied between the base terminal B and the emitter terminal E.

When the forward voltage is applied between the base terminal B and the emitter terminal E, a forward amplified current may flow between the collector terminal C and the emitter terminal E. In other words, the current of the battery 160 may be supplied to the controller 170.

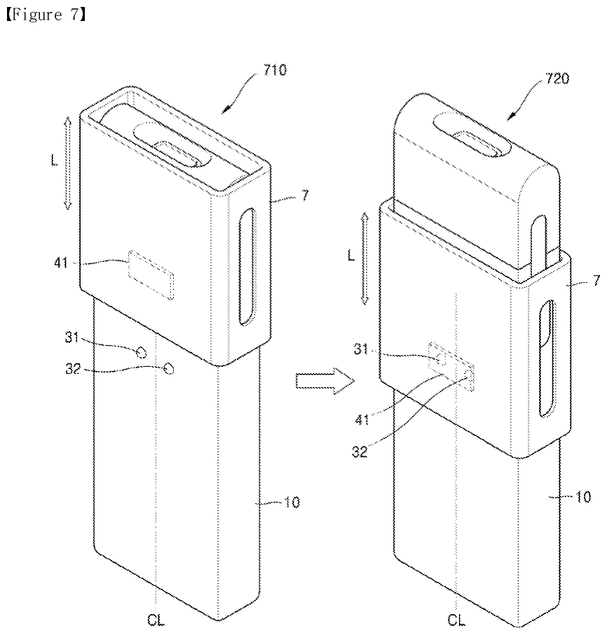

FIGS. 7 through 9 illustrate examples of a power supply method according to a first embodiment.

Referring to FIGS. 7 through 9, the slider 7 may be coupled to the main body 10 to be movable between the first position and the second position. The first position may be a position where the end of the mouthpiece is covered by the slider 7, and the second position may be a position where the end of the mouthpiece is exposed to the outside.

The slider 7 may be moved from the first position to the second position and from the second position to the first position along the main body 10. The conductive member 41 may be arranged on the inner surface of the slider 7 and may connect the first electrode 31 and the second electrode 32 to each other when the slider 7 is at the second position. When the first electrode 31 and the second electrode 32 are connected to each other, the power supply unit 150 may supply power to the controller 170.

When receiving power, the controller 170 may exit the standby mode to heat the heater 140.

In FIG. 7, the left drawing 710 shows a state in which the slider 7 is located at the first position, and the right drawing 720 showing a state in which the slider 7 is located at the second position. In FIG. 7, the first electrode 31 and the second electrode 32 may be arranged symmetrically with respect to the central longitudinal line CL of the main body 10.

The conductive member 41 may not be in contact with any one of the first electrode 31 and the second electrode 32 while the slider 7 covers the mouthpiece (i.e., at the first position). The conductive member 41 may be in contact with the first electrode 31 and the second electrode 32 while the slider 7 exposes the mouthpiece (i.e., at the second position).

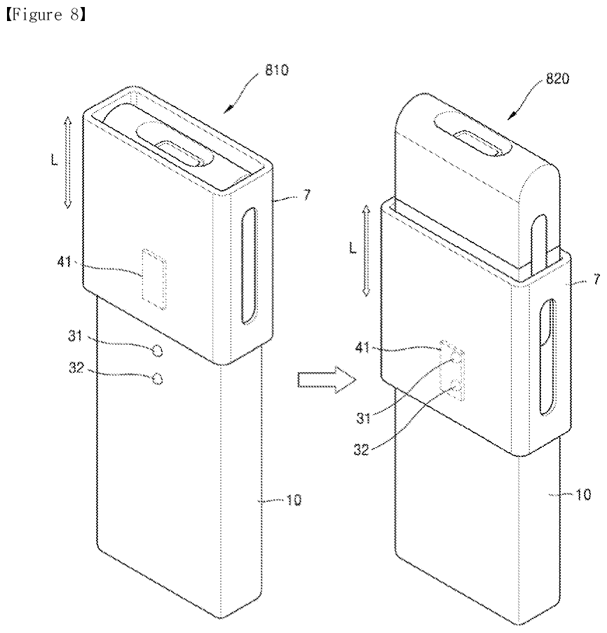

Because the first electrode 31 and the second electrode 32 are arranged symmetrically with respect to the central longitudinal line CL of the main body 10, the aerosol generating device 5 of FIG. 7 may more stably fix the slider 7 against an external force in the longitudinal direction L, when compared to FIG. 8 which will be described below.

In FIG. 8, the left drawing 810 shows a state in which the slider 7 is located at the first position, and the right drawing 820 shows a state in which the slider 7 is located at the second position. When compared with FIG. 7, the first electrode 31 and the second electrode 32 are arranged to be separated along the longitudinal direction L of the main body 10.

The conductive member 41 may not be in contact with any one of the first electrode 31 and the second electrode 32 while the slider 7 is at the first position. On the other hand, the conductive member 41 may be in contact with the first electrode 31 while the slider 7 is positioned between the first position and the second position. Also, the conductive member 41 may be in contact with the first electrode 31 and the second electrode 32 while the slider 7 is at the second position.

In the aerosol generating device 5 of FIG. 8, since the conductive member 41 only contacts the first electrode 31 while it is between the first position and the second position, accidental operation of the aerosol generating device by slight sliding movement of the slider 7 may be prevented.

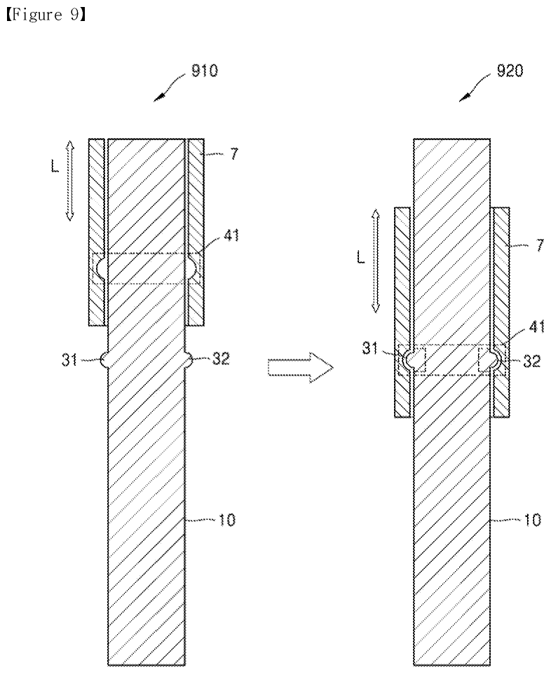

FIG. 9 is a side view of the aerosol generating device 5 having two electrodes on different sides of the main body according to the viewing direction A1 of FIGS. 2 and 3. In more detail, in FIG. 9, the left drawing 910 shows a state in which the slider 7 is located at the first position, and the right drawing 920 shows a state in which the slider 7 is located at the second position. When compared with FIGS. 7 and 8, the first electrode 31 and the second electrode 32 are arranged on different side surfaces of the main body 10.

The first electrode 31 may be arranged on one side surface of the main body 10, and the second electrode 32 may be arranged on another side surface of the main body 10. Also, the conductive member 41 may be arranged on the inner surface of the slider 7, and at least a portion of the conductive member 41 may be exposed to the outside. The conductive member 41 may extend in a direction perpendicular to the longitudinal direction L for electrical contact with the first electrode 31 and the second electrode 32.

The conductive member 41 may not in contact with any one of the first electrode 31 and the second electrode 32 when the slider 7 is at the first position. On the other hand, the conductive member 41 may be simultaneously in contact with the first electrode 31 and the second electrode 32 when the slider 7 is at the second position.

Since the first electrode 31 and the second electrode 32 are arranged on different side surfaces of the main body 10 in FIG. 9, the slider 7 may be more stably fixed against the external force in the longitudinal direction L, when compared to FIGS. 7 and 8.

In the power supply method according to the first embodiment described above, the controller 170 may be quickly waken up because power is supplied to the controller 170 as soon as the conductive member 41 comes in contact with the electrodes 31 and 32. Also, a heating time of the heater 140 may be significantly reduced.

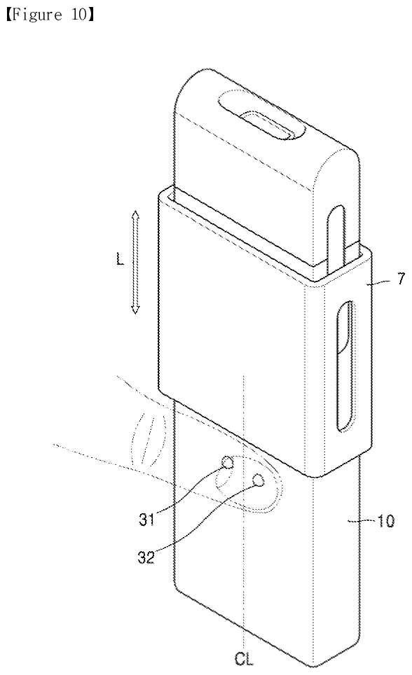

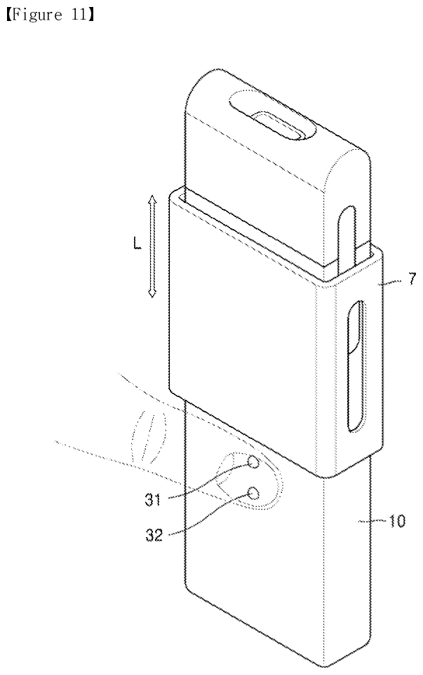

FIGS. 10 through 12 illustrate examples of a power supply method according to a second embodiment.

Referring to FIGS. 10 through 12, the first electrode 31 and the second electrode 32 may come in electrical contact with each other by the user's touch input. For example, the first electrode 31 and the second electrode 32 may be in electrical contact with each other by the user's finger.

When the first electrode 31 and the second electrode 32 are in electrical contact with each other, the power supply unit 150 may supply power to the controller 170, and the controller 170 may exit the standby mode to heat the heater 140.

FIGS. 10 through 12 illustrate different ways of making a user touch input according to the different arrangements of the first electrode 31 and the second electrode 32.

For example, as shown in FIG. 10, when the first electrode 31 and the second electrode 32 are arranged symmetrically with respect to the central longitudinal line CL of the main body 10, the user may simultaneously touch the first electrode 31 and the second electrode 32 by using a thumb.

Similarly, as shown in FIG. 11, when the first electrode 31 and the second electrode 32 are arranged along the longitudinal direction L of the main body 10, the user may simultaneously touch the first electrode 31 and the second electrode 32 by using a thumb.

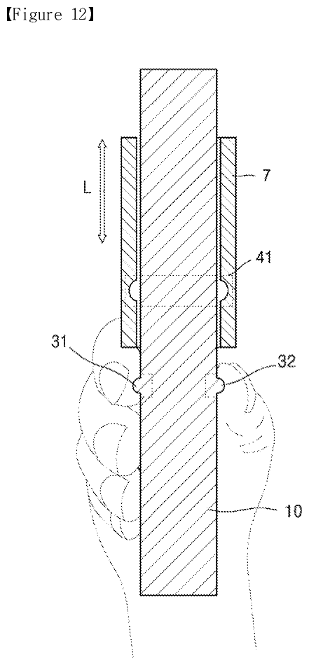

As shown in FIG. 12, when the first electrode 31 and the second electrode 32 are arranged on different side surfaces of the main body 10, the first electrode 31 may be in contact with the user's thumb, and the second electrode 32 may be in contact with the user's index finger.

In the power supply method according to the second embodiment described above, because power supply to the controller 170 is triggered by the user's touch input, accidental operation of the aerosol generating device by an external force that is not intended by the user may be prevented.

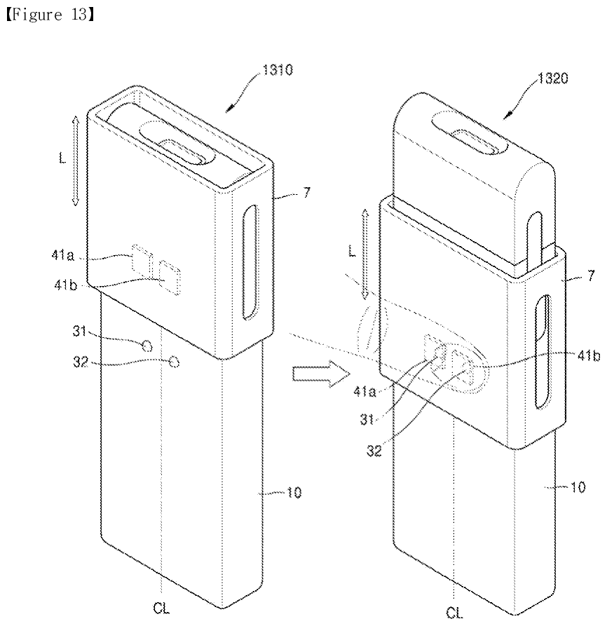

FIGS. 13 through 15 illustrate examples of a power supply method according to a third embodiment.

Referring to FIGS. 13 through 15, the slider 7 may be coupled to the main body 10 to be movable between the first position and the second position. The first position may be a position where the end of the mouthpiece is covered by the slider 7, and the second position may be a position where the end of the mouthpiece is exposed to the outside.

The slider 7 may be moved from the first position to the second position and from the second position to the first position along the main body 10. The first conductive member 41a and the second conductive member 42a may be formed through the slider 7.

When the slider 7 is at the second position, the first conductive member 41a may be in contact with the first electrode 31, and the second conductive member 41b may be in contact with the second electrode 32. The first conductive member 41a and the second conductive member 42b are formed through the slider 7, such that at least a portion of the first conductive member 41a and the second conductive member 42b may be exposed to the outside.

Since the first conductive member 41a and the second conductive member 41b are separated, simply moving the slider 7 to the second position does not automatically provide an electrical contact between the first electrode 31 and the second electrode 32. Instead, the first electrode 31 and the second electrode 32 may come in electrical contact with each other by the user's touch input for connecting the first conductive member 41a and the second conductive member 41b while the slider 7 is at the second position.

When the first electrode 31 and the second electrode 32 are in electrical contact with each other, the power supply unit 150 may supply power to the controller 170, and the controller 170 may exit the standby mode to heat the heater 140.

In FIG. 13, the left drawing 1310 shows a state in which the slider 7 is located at the first position, and the right drawing 1320 shows a state in which the slider 7 is located at the second position. In FIG. 13, the first electrode 31 and the second electrode 32 may be arranged symmetrically with respect to the central longitudinal line CL of the main body 10.

The first conductive member 41a and the second conductive member 41b may not be in contact with any one of the first electrode 31 and the second electrode 32 at the first position. The first conductive member 41a and the second conductive member 41b may be in contact with the first electrode 31 and the second electrode 32, respectively, at the second position. The first electrode 31 and the second electrode 32 may be in electrical contact with each other by the user's touch input of simultaneously touching the first conductive member 41a and the second conductive member 41b while the slider 7 is at the second position.

Because the first electrode 31 and the second electrode 32 are arranged symmetrically with respect to the central longitudinal line CL of the main body 10, the aerosol generating device 5 of FIG. 13 includes all the advantages described in FIG. 7. Also, because the first electrode 31 and the second electrode 32 are in electrical contact with each other by the user's touch input, the aerosol generating device 5 of FIG. 13 includes all of the advantages described in FIGS. 10 through 12. In other words, in the aerosol generating device 5 of FIG. 13, the slider 7 may be stably fixed against the external force of the longitudinal direction L, and accidental operation of the aerosol generating device by unintentional movement of the slider 7 may be prevented.

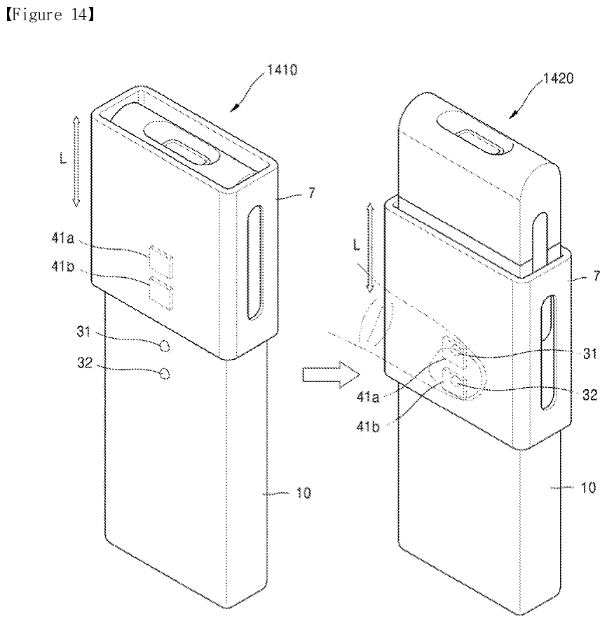

In FIG. 14, the left drawing 1410 shows a state in which the slider 7 is located at the first position, and the right drawing 1420 shows a state in which the slider 7 is located at the second position. In FIG. 14, the first electrode 31 and the second electrode 32 may be arranged along the central longitudinal line CL of the main body 10.

The first conductive member 41a and the second conductive member 41b may not be in contact with any one of the first electrode 31 and the second electrode 32 at the first position. Also, the second conductive member 41b may be in contact with the first electrode 31 between the first position and the second position. Also, the first conductive member 41a may be in contact with the first electrode 31 at the second position, and the second conductive member 41b may be in contact with the second electrode 32 at the second position.

The first electrode 31 and the second electrode 32 may be in electrical contact with each other by the user's touch input of simultaneously touching the first conductive member 41a and the second conductive member 41b while the slider 7 is at the second position.

Because the first electrode 31 and the second electrode 32 are arranged along the central longitudinal line CL of the main body 10, the aerosol generating device 5 of FIG. 14 includes all of the advantages described in FIG. 8. Also, because the first electrode 31 and the second electrode 32 are in electrical contact with each other by the user's touch input, the aerosol generating device 5 of FIG. 14 includes all of the advantages described in FIGS. 10 through 12. In other words, the aerosol generating device 5 of FIG. 14 may prevent accidental operation of the aerosol generating device 5 by unintentional movement of the slider 7.

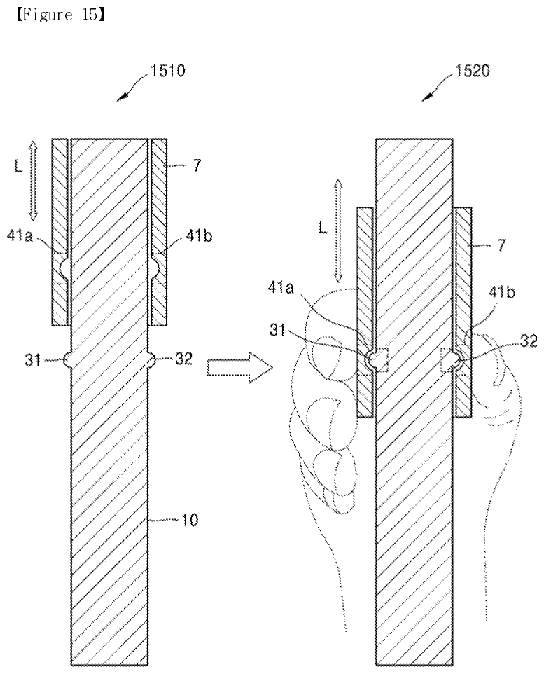

FIG. 15 is a side view of the aerosol generating device having the electrodes on different sides, according to the direction A1 of FIGS. 2 and 3. In more detail, in FIG. 15, the left drawing 1510 shows a state in which the slider 7 is located at the first position, and the right drawing 1520 shows a state in which the slider 7 is located at the second position. When compared with FIGS. 13 and 14, the first electrode 31 and the second electrode 32 are arranged on different side surfaces of the main body 10 in FIG. 15. Also, in the aerosol generating device 5 of FIG. 15, the first electrode 31 and the second electrode 32 are separated from each other, unlike the embodiment shown in FIG. 9, and they only come in electrical contact with each other by the user's touch input of simultaneously touching the first conductive member 41a and the second conductive member 41b.

The first conductive member 41a and the second conductive member 41b may not be in contact with any one of the first electrode 31 and the second electrode 32 when the slider 7 is at the first position. When the slider 7 is at the second position, the first conductive member 41a may be in contact with the first electrode 31 at the second position, and the second conductive member 41b may be in contact with the second electrode 32 at the second position.

The first electrode 31 and the second electrode 32 may come in electrical contact with each other by the user's touch input of simultaneously touching the first conductive member 41a and the second conductive member 41b while the slider 7 is at the second position. For example, the first conductive member 41a may be in contact with the user's thumb, and the second conductive member 41b may be in contact with the user's index finger. Since the first conductive member 41a and the second conductive member 41b are separated, simply moving the slider 7 to the second position does not automatically provide an electrical contact between the first electrode 31 and the second electrode 32. Instead, the first electrode 31 and the second electrode 32 may come in electrical contact with each other by the user's touch input that connects the first conductive member 41a and the second conductive member 41b while the slider 7 is at the second position.

Because the first electrode 31 and the second electrode 32 are arranged on different side surfaces of the main body 10, the aerosol generating device 5 of FIG. 15 includes all of the advantages described in FIG. 9. Also, because the first electrode 31 and the second electrode 32 are in electrical contact with each other by the user's touch input, the aerosol generating device 5 of FIG. 15 includes all of the advantages described in FIGS. 10 through 12. In other words, the aerosol generating device 5 of FIG. 15 may stably fix the slider 7 against the external force of the longitudinal direction L and may prevent accidental operation of the aerosol generating device by unintentional movement of the slider 7.

Those of ordinary skill in the art related to the present embodiments may understand that various changes in form and details can be made therein without departing from the scope of the characteristics described above. The disclosed methods should be considered in a descriptive sense only and not for purposes of limitation. The scope of the present disclosure is shown in the claims rather than the foregoing description, and all differences within the scope equivalent thereto should be construed as being included in the present disclosure.

1. An aerosol generating device comprising:
a main body;
a heater accommodated in the main body and configured to heat an aerosol generating material;
a controller accommodated in the main body and configured to heat the heater; and
a power supply unit comprising a first electrode and a second electrode arranged apart from each other on an outer surface of the main body, and configured to supply power to the controller when the first electrode and the second electrode are connected to each other.

2. The aerosol generating device of claim 1, further comprising a slider comprising at least one conductive member arranged on an inner surface of the slider, and coupled to the main body to be movable between a first position and a second position,
wherein the conductive member connects the first electrode and the second electrode when the slider is at the second position.

3. The aerosol generating device of claim 2, wherein the first electrode comprises a first protrusion, the second electrode comprises a second protrusion, and the conductive member comprises coupling grooves which are coupled to the first protrusion and the second protrusion when the slider is at the second position.

4. The aerosol generating device of claim 1, wherein the first electrode and the second electrode are connected to each other by a user's touch input.

5. The aerosol generating device of claim 1, further comprising a slider comprising a first conductive member and a second conductive member arranged on an inner surface of the slider, and coupled to the main body to be movable between a first position and a second position,
wherein, when the slider is at the second position, the first conductive member is in contact with the first electrode, and the second conductive member is in contact with the second electrode.

6. The aerosol generating device of claim 5, wherein the first electrode and the second electrode are connected to each other by a user's touch input that connects the first conductive member and the second conductive member to each other.

7. The aerosol generating device of claim 1, wherein the first electrode and the second electrode are arranged on one side surface of the main body.

8. The aerosol generating device of claim 7, wherein the first electrode and the second electrode are arranged symmetrically with respect to a central longitudinal line of the main body.

9. The aerosol generating device of claim 7, wherein the first electrode and the second electrode are arranged apart from each other along a central longitudinal line of the main body.

10. The aerosol generating device of claim 1, wherein the first electrode is arranged on one side surface of the main body, and the second electrode is arranged on the other side surface of the main body.

11. The aerosol generating device of claim 1, further comprising a battery configured to supply power to the controller.

12. The aerosol generating device of claim 11, wherein the power supply unit further comprises a switching element configured to connect the battery and the controller when the first electrode and the second electrode are connected to each other, and a resistive element configured to cut off overvoltage of the battery.

13. The aerosol generating device of claim 12, wherein the switching element comprises an NPN transistor.

14. The aerosol generating device of claim 13, wherein
the first electrode is connected to a positive terminal of the battery,
the second electrode is connected to a base terminal of the NPN transistor,
an emitter terminal of the NPN transistor is connected to the controller,
a collector terminal of the NPN transistor is connected to the resistive element, and
the resistive element is connected to a negative terminal of the battery.
